(19) United States
(12) Patent Application Publication
(10) Pub. No.: US 2019/0308282 A1
(43) Pub. Date: Oct. 10, 2019

(54) SOLDER PASTE AND SOLDER JOINT

(71) Applicant: NEC Corporation, Minato-ku, Tokyo (JP)

(72) Inventor: Yuki MOMOKAWA, Tokyo (JP)

(73) Assignee: NEC Corporation, Minato-ku, Tokyo (JP)

(21) Appl. No.: 16/309,159

(22) PCT Filed: Jun. 19, 2017
(86) PCT No.: PCT/JP2017/022446

§ 371 Date: Dec. 12, 2018

(30) Foreign Application Priority Data
Jun. 21, 2016 (JP) 2016-122470

(51) Int. Cl. B23K 35/26; C22C 13/00; B23K 35/02; H05K 3/34

(52) U.S. Cl. CPC B23K 35/262; C22C 13/00; B23K 35/0244; B23K 2101/42; H05K 3/341; H05K 2201/10734; H05K 3/3463

(57) ABSTRACT

The present invention is provided with a solder paste including an additive element without segregation of a low-melting phase while acquiring an additive effect of the additive element in a solder joint that joins electrodes of an electronic component and a printed circuit board. The solder paste is used for mounting an electronic component on a printed circuit board. The solder paste includes a tin-silver-copper based solder alloy to which an additive element other than tin, silver, and copper is added. The solder alloy contains the additive element adjusted to an amount greater than or equal to a minimum amount for exhibiting an additive effect and less than or equal to a solid solubility limit in a solder joint formed between electrodes of the printed circuit board and the electronic component when the electronic component is mounted on the printed circuit board.

### TECHNICAL FIELD

The present invention relates to a solder paste including a tin-silver-copper based solder alloy and a solder joint. The present invention particularly relates to a solder paste including a tin-silver-copper based solder alloy to which an additive element other than tin, silver, and copper is added and a solder joint.

### BACKGROUND ART

A price of a solder alloy containing silver has been rising due to an increase in a price of silver. Thus, as a measure to reduce a cost of a solder alloy containing silver, a low silver solder alloy having a reduced content of silver, such as an Sn-1.0Ag-0.7Cu alloy and an Sn-0.3Ag-0.7Cu alloy, has been receiving attention (Sn: tin, Ag: silver, and Cu: copper). However, an increase in a melting point of a solder alloy, a decrease in strength due to a decrease in amount of Ag₃Sn compound in a joint, and a decrease in reliability are concerned when silver in a solder alloy is reduced. With regard to the low silver solder alloy, an element other than copper in a minute amount may be added for the purpose of increasing mechanical strength of a solder alloy.

Further, a high silver solder alloy containing silver at a relatively high concentration (about 3 to 5%) is used in a field that needs a high strength solder alloy, such as automotive applications. The high silver solder alloy also increases mechanical strength by adding and solid-solving an element other than copper in tin. In other words, adding an element other than copper in a solder alloy containing silver can improve a characteristic of solder regardless of a content of silver.

PTLs 1 to 5 disclose a solder alloy obtained by adding an element other than copper to a lead-free solder alloy containing silver. PTLs 1 to 5 disclose examples in which elements such as magnesium, aluminum, silicon, phosphorus, calcium, manganese, iron, cobalt, nickel, zinc, gallium, germanium, zirconium, antimony, indium, and bismuth are added, for example.

### CITATION LIST

### Patent Literature

[PTL 1] Japanese Patent No. 2752258

[PTL 2] Japanese Unexamined Patent Application Publication No. 2004-154845

[PTL 3] Japanese Unexamined Patent Application Publication No. 2007-268569

[PTL 4] Japanese Unexamined Patent Application Publication (Translation of PCT Application) No. 2009-506203

[PTL 5] Japanese Unexamined Patent Application Publication No. 2011-5510

### SUMMARY OF INVENTION

### Technical Problem

When a ball grid array (BGA) is mounted on a printed circuit board, a solder ball of the BGA melts with a solder paste printed on wiring. An SnAgCu based alloy that does not contain an additive element is used for the solder ball of the BGA. In such a case, a content of the additive element decreases in the entire solder joint in which the solder paste fuses with a solder alloy included in the solder ball, and thus an effect of improving a joint characteristic may not be exhibited.

In contrast, a measure is considered of previously increasing a content of an additive element in a solder alloy in a solder paste and setting a content of an additive element in the entire solder joint to an amount in which an effect of improving joint strength is exhibited. However, for such a measure, an additive element becomes excessive in a solder joint of a component other than a BGA mounted without a solder ball or the like, and thus joint reliability may decrease in cases where the entire solder becomes too hard, an interface crack occurs due to segregation of an additive element in a joint interface, and the like.

In order to solve the above-described problems, an object of the present invention is to provide a solder paste in which an additive element does not become excessive while an additive effect of the additive element is acquired in a solder joint that joins an electrode of an electronic component and an electrode of a printed circuit board.

### Solution to Problem

A solder paste according to one aspect of the present invention is a solder paste for mounting an electronic component on a printed circuit board. The solder paste includes a tin-silver-copper based solder alloy to which an additive element other than tin, silver, and copper is added. The solder alloy contains the additive element adjusted in such a way that the additive element is contained in an amount greater than or equal to a minimum amount for exhibiting an additive effect and less than or equal to a solid solubility limit in a solder joint formed between an electrode of the printed circuit board and an electrode of the electronic component when the electronic component is mounted on the printed circuit board.

A solder joint according to one aspect of the present invention includes a tin-silver-copper based solder alloy to which an additive element other than tin, silver, and copper is added. The solder alloy is formed between an electrode of a printed circuit board and an electrode of an electronic component when the electronic component is mounted on the printed circuit board, and contains the additive element in an amount greater than or equal to a minimum amount for exhibiting an additive effect and less than or equal to a solid solubility limit.

### Advantageous Effects of Invention

According to the present invention, a solder paste including an additive element without segregation of a low-melting phase can be provided while an additive effect of the additive element can be acquired in a solder joint that joins an electrode of an electronic component and an electrode of a printed circuit board.

### BRIEF DESCRIPTION OF DRAWINGS

FIG. 1 is a schematic diagram illustrating one example of a solder joint formed by using a solder paste according to a first example embodiment of the present invention.

FIG. 2 is a schematic diagram of a state where a solder ball of a ball grid array (BGA) faces an electrode on which the solder paste according to the first example embodiment of the present invention is printed.

FIG. 3 is a schematic diagram of a state where the solder ball of the ball grid array (BGA) is placed on the electrode on which the solder paste according to the first example embodiment of the present invention is printed.

FIG. 4 is a schematic diagram of a state where a mounting substrate according to a second example embodiment of the present invention is in a stage of manufacturing.

FIG. 5 is a schematic diagram of a mounting substrate according to the second example embodiment of the present invention.

FIG. 6 is a schematic diagram of an electronic apparatus equipped with the mounting substrate according to the second example embodiment of the present invention.

### EXAMPLE EMBODIMENT

Hereinafter, example embodiments of the present invention will be described by using drawings. However, limitation technically preferable to the present invention is imposed on the example embodiments described below, but the example embodiments do not limit the scope of the invention to the following. Note that, the same places are provided with the same reference signs in all the drawings used for the description of the example embodiments below unless there is a particular reason. Further, repetitive description of the same configuration and operations may be omitted from the example embodiments below.

### First Example Embodiment

First, a solder paste according to a first example embodiment of the present invention will be described. The solder paste in the present example embodiment relates to a solder paste applied to an electrode of a printed circuit board when an electronic component is mounted on the printed circuit board. The solder paste in the present example embodiment particularly relates to a solder paste applied to an electrode of a printed circuit board when a ball grid array (BGA) and an electronic component other than the BGA are mixed and mounted on the same printed circuit board. Note that, a solder ball of the BGA is not assumed to contain an additive element other than tin, silver, and copper in the present example embodiment. Further, a solder joint formed between an electrode of a printed circuit board and an electrode of an electronic component is also referred to as a solder joint in the present example embodiment.

The solder paste in the present example embodiment includes a solder alloy prepared in such a way that a solder joint formed between an electrode of a printed circuit board and an electrode of an electronic component contains an additive element in an amount for exhibiting additive effects in addition to tin, silver, and copper. Further, an additive element in an amount adjusted not to form a eutectic phase with tin in the solder joint formed between the electrode of the printed circuit board and the electrode of the electronic component is added to the solder alloy included in the solder paste in the present example embodiment.

The solder alloy included in the solder paste in the present example embodiment may be prepared in such a way that the solder joint formed between the electrode of the printed circuit board and the electrode of the BGA contains an additive element in an amount greater than or equal to a minimum amount for exhibiting additive effects. Further, the solder alloy included in the solder paste in the present example embodiment may be prepared in such a way that the solder joint other than the BGA contains an additive element in an amount that does not exceed a sum total of an amount of solid solubility limit to tin, silver, and copper in the solder alloy.

### Solder Paste

First, the solder paste according to the present example embodiment will be described.

The solder paste in the present example embodiment is used to form a solder joint between an electrode (a component electrode hereinafter) of an electronic component including a BGA and an electrode (a substrate electrode hereinafter) formed on a printed circuit board. The solder paste in the present example embodiment is manufactured by mixing materials such as a powder solder alloy, a flux, a solvent, and a thixotropic agent (also referred to as a thixo agent). Note that, materials such as a flux, a solvent, and a thixo agent included in the solder paste in the present example embodiment are not particularly limited.

The solder paste in the present example embodiment includes a solder alloy having a composition in which an additive element other than silver (Ag hereinafter) and copper (Cu hereinafter) is added to an SnAgCu based alloy in which Ag and Cu are added to tin (Sn hereinafter) as a main ingredient.

A kind of the additive element is not particularly limited as long as a desired characteristic is acquired. A point of view of selecting the additive element is that the additive element is solid-solved in the SnAgCu based alloy of the solder alloy and also does not have a eutectic point with the other elements in the solder alloy. When an element that does not have a eutectic point with the other elements in the solder alloy is selected, the additive element can be relatively uniformly dispersed in the SnAgCu based alloy without segregating in a joint interface even in a case where a temperature gradient occurs in a solder joint during soldering. Note that, a eutectic point at less than or equal to a temperature of mounting an electronic component on a printed circuit board is described in the present example embodiment, and a eutectic point in a temperature region exceeding the mounting temperature is not considered.

The solder alloy in the present example embodiment contains an additive element selected from a group consisting of antimony (Sb hereinafter), aluminum (Al hereinafter), calcium (Ca hereinafter), and manganese (Mn hereinafter) in addition to Sn, Ag, and Cu. Sb, Al, Ca, and Mn may be added separately or in combination to the solder alloy in the present example embodiment. When Sb, Al, Ca, and Mn are combined, any of Al, Ca, and Mn is preferably added in addition to Sb. Note that, Sb, Al, Ca, and Mn may be combined in an arbitrary ratio.

The solder alloy included in the solder paste in the present example embodiment may be prepared in such a way that the solder joint formed between the electrode of the printed circuit board and the electrode of the BGA contains an additive element in an amount greater than or equal to a minimum amount for exhibiting additive effects. Further, the solder alloy included in the solder paste in the present example embodiment is prepared in such a way that a solder joint of an electronic component other than the BGA contains an additive element in an amount that does not exceed a sum total of an amount of solid solubility limit to the solder alloy.

A solder joint can have a long life by adding Sb, Al, Ca, and Mn separately or in combination to the SnAgCu based alloy. According to the present example embodiment, a hard fragile layer is not deposited on a joint interface between the substrate electrode and component electrode and the solder while a characteristic of the solder joint is improved by strengthening solid solubility and increasing extension. Thus, the joint interface is not easily broken even when stress is applied to the solder joint.

Additive effects exhibited by adding Sb, Al, Ca, and Mn to the SnAgCu based alloy are described as follows.

Sb is solid-solved in Sn and does not have a eutectic point with the other elements in the solder alloy. Thus, an alloy phase containing an additive element does not segregate even when Sb is added to a typical Sn based solder alloy including the SnAgCu based alloy, and strength of a material can be increased by action of a mechanism for strengthening solid solubility. As a result, an additive element does not lean to a joint interface even when a temperature gradient occurs during formation of a solder joint, and the additive element can be relatively homogeneously dispersed in Sn as a main ingredient.

Further, adding Sb to the SnAgCu based alloy can prevent a hard fragile alloy phase from being deposited on joint interfaces between the substrate electrode and component electrode and a solder joint that joins the substrate electrode and the component electrode in the solder joint while strength of the solder alloy is increased by strengthening solid solubility. In other words, fragile alloy phase breakable with application of stress to a solder joint is not formed in a joint interface by adding Sb to the SnAgCu based alloy.

The three elements of Ca, Mn, and Al have a eutectic point with Sn unlike Sb. However, the eutectic point between each of Ca, Mn, and Al and Sn is close to a melting point of Sn, and a low-melting phase hardly segregates. Further, the three elements of Ca, Mn, and Al have an additive effect of improving extension of a typical Sn based solder alloy. Therefore, adding Ca, Mn, and Al to the SnAgCu based alloy can prevent the additive element from segregating near a joint interface while improving strength and extension of the solder alloy. When the additive element segregates, a crack is more likely to occur in the segregation portion as a starting point or a development path. On the other hand, a solder alloy to which any of Ca, Mn, and Al is added has a long life because an additive element does not segregate near a joint interface.

Further, adding Ca, Mn, and Al to Sn as a main ingredient of a solder alloy achieves the following effect of improving a characteristic while improving extension of the solder alloy. Ca suppresses growth of Sn, CuSn, and an AgSn intermetallic compound in a solder joint. Mn reduces wet time. Although wettability and spreadability tend to slightly decrease, Al suppresses growth of the AgSn intermetallic compound. Note that, CuSn and the AgSn intermetallic compound have hard and fragile characteristics, and may become a starting point of a crack when growing too much.

When Sb is added to the SnAgCu based alloy, strength of a material for a solder alloy is increased by strengthening solid solubility, but extension of the solder alloy decreases. Thus, only adding Sb to the SnAgCu based alloy reduces extension of the solder alloy, which results in a decrease in toughness. As a result, the solder alloy may not have a long life. Accordingly, when Sb is added to the SnAgCu based alloy, strength and extension of the solder alloy are preferably improved by adding any of Ca, Mn, and Al.

A solid solubility limit of Sb to the SnAgCu based alloy is approximately 1.03% by mass. Further, solid solubility limits of the other additive elements to the SnAgCu based alloy are about 0.34% by mass of Ca, about 0.46% by mass of Mn, and about 0.23% by mass of Al. The solid solubility limits are values read from a state diagram of Sn and the additive elements, and include a slight error.

In general, an additive element exceeding a solid solubility limit and being added is excessively solid-solved in a solid alloy by supercooling immediately after soldering. However, when heat and distortion are applied to a solder joint in which the additive element is excessively solid-solved, some of the additive element cannot be solid-solved in the solder alloy and is redeposited. Further, when an intermetallic compound grows in a solder joint interface by a thermal load, Sn is generally consumed in a peripheral portion of the grown intermetallic compound. Thus, a concentration of the additive element relatively increases in the joint interface in which the intermetallic compound grows, and some of the additive element exceeding the solid solubility limit is more likely to be redeposited. When the additive element is redeposited in the solder joint interface, a mechanical characteristic of the solder alloy is greatly influenced. Particularly, when the additive element is deposited in layers in the joint interface, the layer of the deposited additive element may become a starting point and an extension path of a crack.

Since an additive element at less than or equal to a solid solubility limit to the SnAgCu based alloy is solid-solved in the solder alloy in the present example embodiment, an additive element is less likely to be redeposited in a solder joint.

In the points of view described above, a composition suitable for a long life of a solder is described as follows. A solder alloy having the following composition is derived from the points of view as described above, and is not a solder alloy of a kind acquired by combining a plurality of materials without grounds. Further, Sb, Ca, Mn, and Al may coexist.

When Sb is added to the SnAgCu based alloy, additive effects are acquired with addition of greater than or equal to 0.1% by mass of Sb. Further, a solid solubility limit of Sb to the SnAgCu based alloy is 1.03% by mass. Thus, an amount of Sb added to a solder alloy in a solder paste is adjusted in such a way that 0.1 to 1.03% by mass of Sb is contained in a solder joint in the present example embodiment.

When Ca is added to the SnAgCu based alloy, additive effects are acquired with addition of greater than or equal to 0.1% by mass of Ca. Further, a solid solubility limit of Ca to the SnAgCu based alloy is 0.34% by mass. Thus, an amount of Ca added to a solder alloy in a solder paste is adjusted in such a way that 0.1 to 0.34% by mass of Ca is contained in a solder joint in the present example embodiment.

When Mn is added to the SnAgCu based alloy, additive effects are acquired with addition of greater than or equal to 0.1% by mass of Mn. Further, a solid solubility limit of Mn to the SnAgCu based alloy is 0.46% by mass. Thus, an amount of Mn added to a solder alloy in a solder paste is adjusted in such a way that 0.1 to 0.46% by mass of Mn is contained in a solder joint in the present example embodiment.

When Al is added to the SnAgCu based alloy, additive effects are acquired with addition of greater than or equal to 0.1% by mass of Al. Further, a solid solubility limit of Al to the SnAgCu based alloy is 0.23% by mass. Thus, an amount of Al added to a solder alloy in a solder paste is adjusted in such a way that 0.1 to 0.23% by mass of Al is contained in a solder joint in the present example embodiment.

As described above, an amount of Sb, Ca, Mn, and Al added to a solder alloy in a solder paste is set to a minimum amount for exhibiting additive effects in a solder joint as a lower limit and to a solid solubility limit to the SnAgCu based alloy as an upper limit in the present example embodiment.

The above-described composition of the additive element is not a charge composition of the additive element added to a solder alloy in a solder paste, and is a composition of the additive element in a solder joint formed between an electrode of an electronic component and an electrode of a printed circuit board after mounting. A solder ball installed on a BGA is assumed to be the SnAgCu based alloy to which an additive element other than Ag and Cu is not added in the present example embodiment. Thus, when a composition of a solder alloy in a solder paste is set as described above, the additive element is diluted by the SnAgCu based alloy in the solder ball, and a composition ratio of the additive element in the solder joint is smaller than an appropriate numerical value.

Thus, in the present example embodiment, an additive amount of the additive element is prepared in such a way that a composition ratio of the additive element in the solder joint is an appropriate numerical value in consideration of an amount of the SnAgCu alloy of the solder ball of the BGA and an amount of the solder alloy in the solder paste. Note that, since an alloy phase of a material for an electrode and a solder alloy is actually generated in a joint interface between the solder joint and the electrode, it is preferable that a composition of the generated alloy phase is also considered to set an amount of the additive element.

For example, it is assumed that an amount of one solder ball installed on the BGA is Q_{b}, and an amount of a solder alloy in a solder paste used for solder-joining one solder ball is Qₚ. It is also assumed that a ratio of the additive element contained in the solder alloy in the solder paste is Aₚ. At this time, a ratio Aₜₒₜₐₗ of the additive element in the solder joint can be calculated by using Expression 1 below. Note that, an amount of the solder alloy and a ratio of the additive element are set in the same system of units.

Aₜₒₜₐₗ=Aₚ×Qₚ/(Q_{b}+Qₚ) (1)

Then, the ratio Aₚ of the additive element that needs to be contained in the solder alloy in the solder paste can be calculated by using Expression 2 transformed from Expression 1.

Aₚ=Aₜₒₜₐₗ×(Q_{b}+Qₚ)/Qₚ=Aₜₒₜₐₗ×(Q_{b}/Qₚ+1) (2)

In other words, when the ratio Aₚ of the additive element that needs to be contained in the solder alloy in the solder paste is set to less than or equal to a sum total Aₗᵢₘᵢₜ of a solid solubility limit of the additive element to the SnAgCu alloy of the solder joint, additive effects of the additive element can be acquired. That is, in the present example embodiment, the ratio Aₚ of the additive element that needs to be contained in the solder alloy in the solder paste may be prepared in such a way as to satisfy Expression 3 below.

Aₚ=Aₜₒₜₐₗ×(Q_{b}/Qₚ+1)≤Aₗᵢₘᵢₜ (3)

When the amount Q_{b} of one solder ball of the BGA is known, the amount of the additive element that needs to be added to the solder joint can be obtained from Expression 3. The amount of the additive element contained in the solder joint can be set by the ratio of the additive element in the solder alloy in the solder paste and the amount of the solder paste including the solder alloy.

Note that, the ratio Aₚ of the additive element may be considered at a mass ratio to consider the amount of the solder alloy by mass. In this case, the ratio Aₚ of the additive element may be set in such a way as to satisfy Expression 4 below.

Aₚ=Aₜₒₜₐₗ×(W_{b}/Wₚ+1)≤Aₗᵢₘᵢₜ (4)

Provided that W_{b} is a mass of one solder ball installed on the BGA, and Wₚ is a mass of one solder alloy in the solder paste used for solder-joining the solder ball in Expression 4. In this case, a ratio (weight ratio and mass ratio) of a mass such as mass % is used for the ratio Aₚ of the additive element and the sum total Aₗᵢₘᵢₜ of the solid solubility limit of the additive element.

Further, the ratio Aₚ of the additive element may be considered at a volume ratio to consider the amount of the solder alloy by volume. In this case, the ratio Aₚ of the additive element may be set in such a way as to satisfy Expression 5 below.

Aₚ=Aₜₒₜₐₗ×(V_{b}/Vₚ+1)≤Aₗᵢₘᵢₜ (5)

Provided that V_{b} is a volume of one solder ball installed on the BGA, and Vₚ is a volume of the solder alloy in the solder paste used for solder-joining one solder ball in Expression 5. In this case, a ratio of a volume such as volume % is used for the ratio Aₚ of the additive element and the sum total Aₗᵢₘᵢₜ of the solid solubility limit of the additive element.

For example, when a supply amount of the solder paste to a supply target of the solder paste is fixed, a ratio of the additive element in the solder alloy may be changed for each supply target. Further, when a solder paste having the same composition is used for all supply targets, a supply amount of the solder paste may be changed for each supply target.

Note that, the supply target of the solder paste is a substrate electrode of a printed circuit board with which a component electrode of a BGA or another electronic component forms a solder joint. A surface state of the component electrode of the electronic component varies by component. For example, for the BGA, a solder joint is formed by melting the solder ball of the BGA and the solder alloy in the solder paste applied to the substrate electrode. Further, for example, for the electronic component including a solder-plated terminal, a solder joint is formed by melting the solder plating applied to the terminal and the solder alloy in the solder paste applied to the substrate electrode. Further, for example, for the electronic component including an Sn-plated terminal, a solder joint is formed by melting the Sn plating applied to the terminal and the solder alloy in the solder paste applied to the substrate electrode.

For the electronic component including a terminal without plating, a solder joint is formed with the terminal itself and the solder alloy in the solder paste applied to the substrate electrode. Thus, when a ratio of the additive element contained in the solder alloy in the solder paste is set similarly to that of the BGA, the ratio of the additive element in the solder joint may exceed a solid solubility limit. Accordingly, an upper limit of the ratio of the additive element contained in the solder alloy in the solder paste is preferably less than or equal to the solid solubility limit of the additive element to the solder alloy. When an upper limit of the ratio of the additive element contained in the solder alloy in the solder paste is less than or equal to the solid solubility limit of the additive element to the solder alloy, the ratio of the additive element does not exceed the solid solubility limit in any solder joint.

Further, a lower limit value of the additive element added to the solder alloy in the solder paste needs to be set at a ratio in which additive effects exhibited by adding the additive element are acquired in the solder joint. A factor to reduce the ratio of the additive element in the solder joint is in the case of a ratio of the additive element in solder plating applied to the solder ball of the BGA and the terminal of the electronic component other than the BGA is small or not included.

In general, an additive element added to a solder alloy in a solder paste decreases to a minimum in a combination with a solder ball of a BGA having a great amount of the solder alloy. In other words, an additive element in a solder joint decreasing to a minimum is in a solder joint of a BGA. Thus, a ratio of the additive element contained in the solder alloy in the solder paste may be set with reference to the solder ball of the BGA. Particularly, a ratio of the additive element in the solder alloy in the solder paste may be set in such a way that a ratio of the additive elements in the solder joint formed by the largest solder ball of solder balls of the BGA mounted on the printed circuit board exceeds the above-described lower limit value.

From the points of view above, a ratio of the additive element in the solder alloy in the solder paste used when the electronic component including the BGA is mounted on the printed circuit board may be set with reference to the following.

A lower limit value of the ratio of the additive element in the solder alloy in the solder paste is set with reference to the time when the solder joint is formed by the solder ball of the BGA and the solder alloy in the solder paste.

An upper limit value of the ratio of the additive element in the solder alloy in the solder paste is less than or equal to the solid solubility limit of the additive element to the solder alloy.

By setting the ratio of the additive element in the solder alloy in the solder paste between the lower limit value and the upper limit value described above, a solder paste capable of suppressing formation of a low-melting phase can be provided while additive effects of the additive element can be acquired in the solder joint.

### Solder Joint

Herein, a solder joint that joins an electrode of an electronic component mounted by using the solder paste in the present example embodiment and an electrode of a printed circuit board will be described with reference to the drawings. The BGA is also taken as an example of the electronic component in the following description.

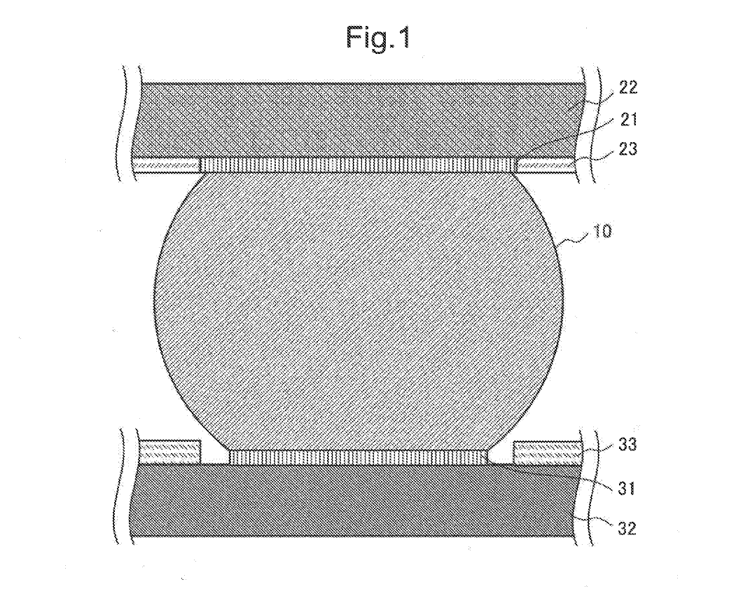

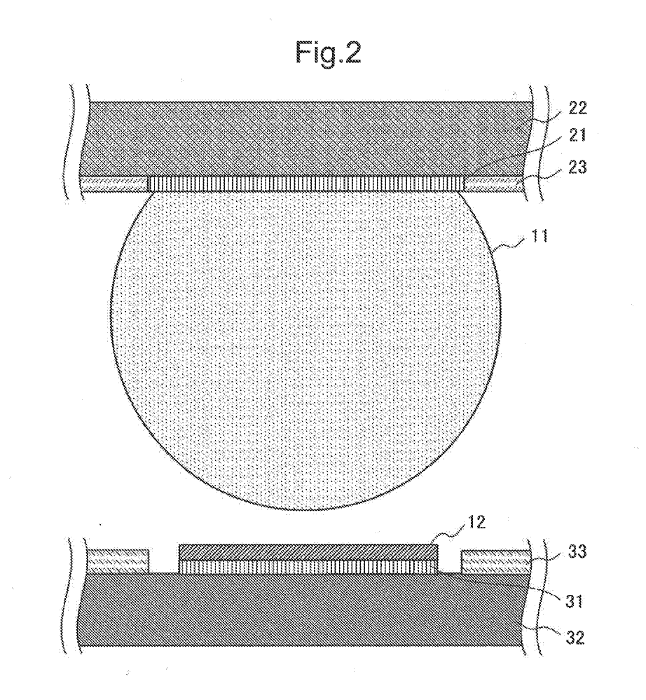

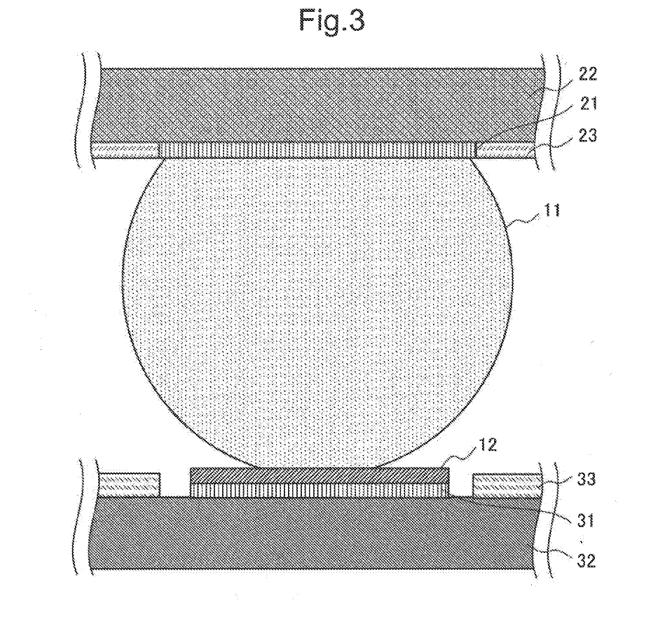

FIG. 1 is a schematic diagram illustrating a vicinity of a solder joint 10 formed by using the solder paste according to the present example embodiment. FIG. 2 is a schematic diagram illustrating a state before the BGA is mounted on the printed circuit board. FIG. 3 is a schematic diagram illustrating a state before reflow with the BGA mounted on the printed circuit board. Note that, FIGS. 1 to 3 illustrate the vicinity of the solder joint 10 and do not illustrate a major portion of a configuration included in the BGA and the printed circuit board.

As in FIG. 2, a component electrode 21 and a solder mask 23 are formed on a base material 22 of the BGA. The component electrode 21 is electrically connected to wiring constituting the BGA. A solder ball 11 is installed on the component electrode 21 of the BGA.

Further, as illustrated in FIG. 2, a substrate electrode 31 and a resist 33 are formed on a main surface of a wiring substrate 32 of the printed circuit board on which the BGA is to be mounted. The substrate electrode 31 is electrically connected to wiring of the printed circuit board. A solder paste 12 for solder-joining the solder ball 11 and the substrate electrode 31 is applied to the substrate electrode 31. As in FIG. 3, the solder joint 10 in FIG. 1 is formed by reflow while the solder ball 11 installed on the BGA is installed on the substrate electrode 31 to which the solder paste 12 is applied. In other words, the solder joint 10 is formed by melting the solder ball 11 and the solder paste 12 when reflow is performed on the printed circuit board on which the electronic component including the BGA is mounted in an appropriate temperature profile.

The solder joint 10 is a joint mechanically and electrically connecting the component electrode 21 and the substrate electrode 31. In the present example embodiment, a ratio of an additive element in the solder joint 10 is set between a lower limit value with which additive effects of the additive element are acquired and a solid solubility limit of the additive element.

### Method of Manufacturing Solder Alloy

Herein, one example of a method of manufacturing the solder alloy in the solder paste according to the present example embodiment will be described. Note that, an example of forming a powder solder alloy in the solder paste will be described in the present example embodiment.

First, weighing is performed on each of elements in such a way that the elements have a desired composition, and the elements are melted at a desired temperature in a vacuum melting furnace to manufacture a bulk alloy.

Then, the manufactured bulk alloy is molded into solder powder having a desired size. For example, a gas atomization method, a centrifugal atomization method, and the like may be used as a method of molding solder powder. When solder powder is molded by these methods, molten metal obtained by melting a bulk alloy prepared in advance is solidified into a spherical shape using an inert gas such as argon and nitrogen. At this time, it is preferable that a container for keeping the molten metal is also maintained in an atmosphere of an inert gas to prevent oxidation of the molten metal. Note that, it is preferable that an inert gas other than nitrogen is used in an alloy composition in the present example embodiment. The reason is that, when Mn is included as an additive element, Mn is nitrided with nitrogen used as an inert gas and surface tension of a solder thus increases, which increases a possibility that the solder powder cannot be molded to have a desired diameter. When Mn is included as an additive element, solder powder can be efficiently manufactured by using an inert gas such as argon to suppress nitriding of Mn.

As described above, according to the present example embodiment, while additive effects of an additive element are acquired in a solder joint that joins an electrode of an electronic component and an electrode of a printed circuit board, a solder paste capable of forming the solder joint in which generation of a low-melting phase is suppressed can be provided.

Further, according to the present example embodiment, a decrease in reliability due to a crack caused by a repetitive thermal load and mechanical distortion can be suppressed in the solder joint that joins the electrode of the electronic component and the electrode of the printed circuit board. As a result, the solder joint formed by using the paste in the present example embodiment can have a longer life than that of a solder joint to which an additive element is not added.

### Second Example Embodiment

Next, a second example embodiment of the present invention will be described. A mounting substrate in the present example embodiment is an electronic component mounted on a printed circuit board by using the solder paste in the first example embodiment.

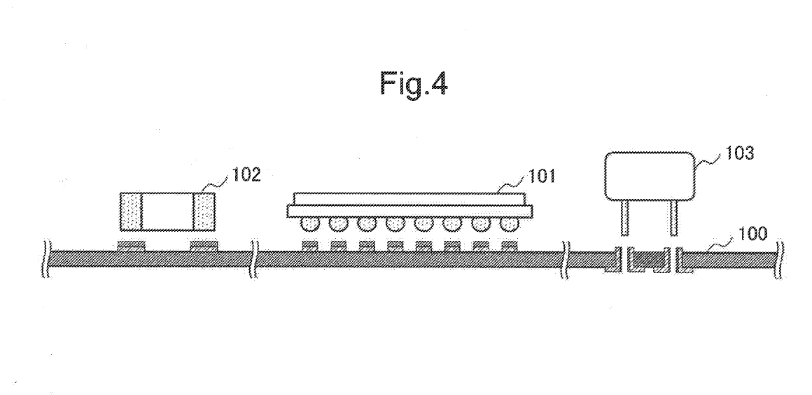

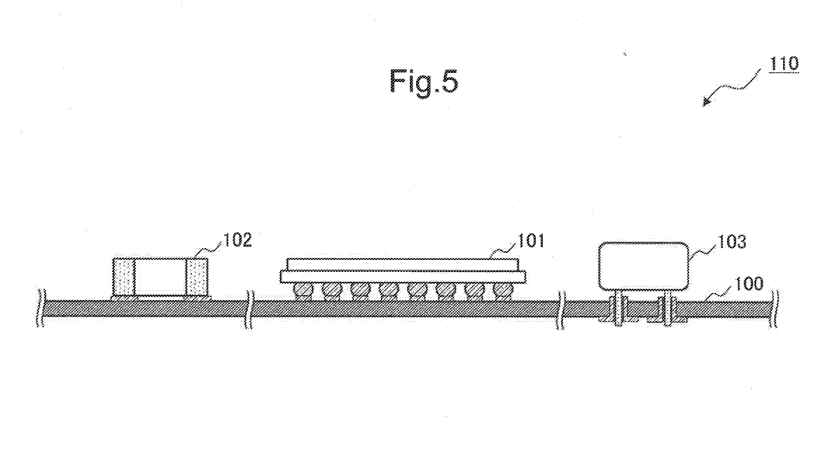

The mounting substrate according to the present example embodiment is also equipped with an electronic component other than a BGA. FIGS. 4 and 5 are schematic diagrams each illustrating an example of mounting a plurality of electronic components including a BGA on the same printed circuit board.

FIG. 4 is a schematic diagram illustrating a state before the plurality of electronic components are mounted on a printed circuit board 100. In the example of FIG. 4, a BGA 101, a surface mounting component 102, and an insertion component 103 are mounted on the printed circuit board 100.

When the BGA 101, the surface mounting component 102, and the insertion component 103 are mounted on the printed circuit board 100, the solder paste in the first example embodiment is previously printed on a substrate electrode corresponding to a component electrode of each of the electronic components. The solder paste can be printed on an electrode of the printed circuit board 100 by using a squeegee via a metal mask in which a position of the substrate electrode is open. Further, the solder paste may be printed on an electrode of the printed circuit board 100 by using a dispenser that drops the solder paste onto the substrate electrode of the printed circuit board 100. FIG. 4 illustrates a state where the solder paste is printed on electrodes of the printed circuit board 100 to form a solder joint between the electrodes of the electronic components.

FIG. 5 is a schematic diagram of a mounting substrate 110 including the plurality of electronic components mounted on the printed circuit board 100. The BGA 101, the surface mounting component 102, and the insertion component 103 are mounted on the mounting substrate 110 in FIG. 5. A solder joint is formed between the component electrode of each of the electronic components and the substrate electrode of the printed circuit board 100. Additive effects of an additive element are acquired between the electrode of each of the electronic components and the electrode of the printed circuit board 100, and the solder joint in which generation of a low-melting phase is suppressed is formed.

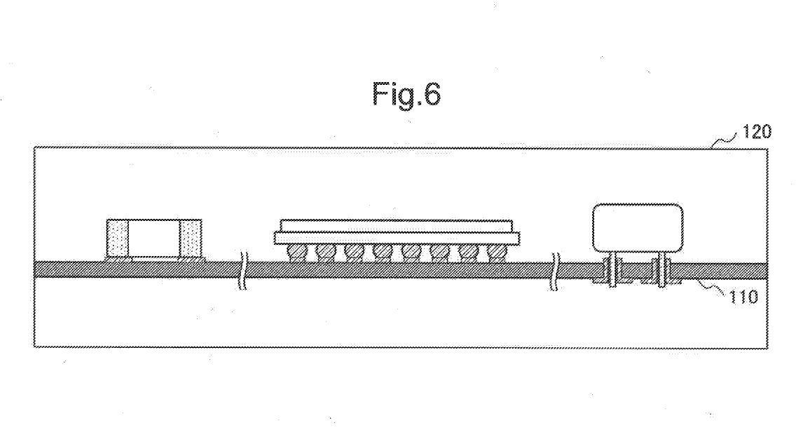

FIG. 6 is a schematic diagram of an electronic apparatus 120 equipped with the mounting substrate in the present example embodiment. For example, an electronic component such as the BGA 101, the surface mounting component 102, and the insertion component 103 are installed on the mounting substrate 110 included in the electronic apparatus 120 such as a computer and a server. Note that, an electronic component such as the surface mounting component 102 and the insertion component 103 may be installed on the mounting substrate 110 installed in the electronic apparatus 120 other than a computer and a server.

According to the present example embodiment, a mounting substrate in which a high degree of reliability is acquired from all solder joints of electronic components mounted on a mounting substrate is acquired. Further, according to the present example embodiment, laminated deposition of an additive element can be suppressed around a solder joint interface by optimizing an additive ratio of the additive element, generation and extension of a crack in the additive element and an interface can be prevented, and a solder joint and an electronic apparatus having a high degree of reliability can be achieved.

Although the present invention has been described with reference to the example embodiments, the present invention is not limited to the above-described example embodiments. Various modifications that can be understood by those skilled in the art within the scope of the present invention may be applied to the configuration and the details of the present invention.

This application is based upon and claims the benefit of priority from Japanese Patent Application No. 2016-122470, filed on Jun. 21, 2016, the disclosure of which is incorporated herein in its entirety by reference.

### REFERENCE SIGNS LIST

10 Solder joint
11 Solder ball
12 Solder paste
21 Component electrode
22 Base material
23 Solder mask
31 Substrate electrode
32 Wiring substrate

### 33 Resist

What is claimed is:

1. A solder paste for mounting an electronic component on a printed circuit board, comprising:
a tin-silver-copper based solder alloy to which an additive element other than tin, silver, and copper is added, wherein
the solder alloy contains the additive element adjusted in such a way that the additive element is contained in an amount greater than or equal to a minimum amount for exhibiting an additive effect and less than or equal to a solid solubility limit in a solder joint formed between an electrode of the printed circuit board and an electrode of the electronic component when the electronic component is mounted on the printed circuit board.

2. The solder paste according to claim 1, wherein
the solder alloy contains at least one kind of the additive element to be selected from a group of antimony, aluminum, calcium, and manganese.

3. The solder paste according to claim 1, wherein
the solder alloy contains antimony and also at least one kind of an element to be selected from a group of aluminum, calcium, and manganese.

4. The solder paste according to claim 1,
being used for mounting the electronic component including a ball grid array (BGA) on the printed circuit board, wherein,
in a mounting substrate on which the electronic component is mounted, the solder alloy contains the additive element in an amount greater than or equal to a minimum amount for exhibiting an additive effect of the additive element in the solder joint of the BGA, and contains the additive element prepared in such a way that the additive element is contained in an amount that does not exceed a sum total of solid solubility amounts to tin, silver, and copper in the solder joint of the electronic component other than the BGA.

5. The solder paste according to claim 4, wherein
a content of the additive element in the solder joint is expressed by an expression:
Aₚ=Aₜₒₜₐₗ(1+Q_{b}/Qₚ)≤Aₗᵢₘᵢₜ
where Aₚ is a ratio of the additive element included in a solder paste,
Aₜₒₜₐₗ is a ratio of the additive element included in one of the solder joint of the BGA,
Q_{b} is an amount of solder ball before joining,
Qₚ is an amount of solder paste supplied to an electrode of the printed circuit board for joining one solder ball, and
Aₗᵢₘᵢₜ is a sum total of solid solubility limits of the additive element to tin, silver, and copper contained in one of the solder joint.

6. The solder paste according to claim 5, wherein,
when an amount Q_{b} of solder ball before joining and an amount Qₚ of solder paste supplied to an electrode of the printed circuit board for joining one solder ball of the BGA are expressed by mass, a ratio Aₜₒₜₐₗ of the additive element included in one of the solder joint of the BGA is set to be greater than or equal to 0.01% by mass.

7. The solder paste according to claim 5, wherein,
when an amount Q_{b} of solder ball before joining and an amount Qₚ of solder paste supplied to an electrode of the printed circuit board for joining one solder ball of the BGA are expressed by mass, a maximum value of a content of the additive element included in the solder joint of the electronic component other than the BGA is set to
1.03% by mass when antimony is contained as the additive element,
0.23% by mass when aluminum is contained as the additive element,
0.34% by mass when calcium is contained as the additive element, and
0.46% by mass when manganese is contained as the additive element.

8. A mounting substrate comprising,
by using the solder paste according to claim 1, the solder joint formed between an electrode of the electronic component and an electrode of the printed circuit board.

9. An electronic apparatus comprising:
the mounting substrate according to claim 8.

10. A solder joint comprising:
a tin-silver-copper based solder alloy to which an additive element other than tin, silver, and copper is added, wherein
the solder alloy is formed between an electrode of a printed circuit board and an electrode of an electronic component when the electronic component is mounted on the printed circuit board, and contains the additive element in an amount greater than or equal to a minimum amount for exhibiting an additive effect and less than or equal to a solid solubility limit.
